(19) United States
(12) Patent Application Publication
(10) Pub. No.: US 2026/0075742 A1
(43) Pub. Date: Mar. 12, 2026

(54) ELECTRONIC DEVICE AND CHASSIS

(71) Applicants: INVENTEC (PUDONG) TECHNOLOGY CORPORATION, Shanghai (CN); INVENTEC CORPORATION, Taipei City (TW)

(72) Inventor: Chih-Wei CHUANG, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/186,089

(22) Filed: Apr. 22, 2025

(30) Foreign Application Priority Data
Sep. 11, 2024 (CN) 202411273408.6

(51) Int. Cl. H05K 7/14

(52) U.S. Cl. CPC H05K 7/1489

(57) ABSTRACT

An electronic device includes a chassis and a plurality of power supplies. The chassis includes a supporting tray and a plurality of power supply brackets. The power supply brackets are disposed on the supporting tray. Each of the power supply brackets includes a bracket top plate, a first bracket side plate, and a second bracket side plate. The first bracket side plate and the second bracket side plate are connected to the bracket top plate. The bracket top plate, the first bracket side plate, and the second bracket side plate together define an accommodating space. The first bracket side plate of one of the power supply brackets and the second bracket side plate of an adjacent one of the power supply brackets are held in position. The power supplies are located in the accommodating spaces.

### CROSS-REFERENCE TO RELATED APPLICATIONS

This non-provisional application claims priority under 35 U.S.C. § 119(a) on Patent Application No(s). 202411273408.6 filed in China, on Sep. 11, 2024, the entire contents of which are hereby incorporated by reference.

### BACKGROUND OF THE INVENTION

### Technical Field of the Invention

The present invention relates to an electronic device and a chassis, and more particularly to an electronic device and a chassis including a power supply bracket.

### Description of the Related Art

Modern society is in an era in which the information technology develops rapidly. Most companies use servers to assist in business processing, such as storing programs, files and data, in order to improve work efficiency.

A server is usually provided with a power supply bracket for mounting multiple power supplies. The current power supply bracket is dedicated to a specific number of power supplies and is configured by a housing and a partition defining a plurality of spaces for the power supplies to be installed therein. However, when the user wants to increases or decreases the number of power supplies installed in the server, one new power supply bracket whose space is adjusted according to the change of the number of the power supplies is required, and the original power supply brackets cannot be used and cause waste, thereby increasing the cost for assembling the power supply bracket. Therefore, how to reduce the cost for assembling the power supply bracket is one of the problems that researchers should solve.

### SUMMARY OF THE INVENTION

The invention provides an electronic device and chassis to reduce the cost for assembling the power supply brackets.

An embodiment of the electronic device disclosed in the present invention includes a chassis and a plurality of power supplies. The chassis includes a supporting tray and a plurality of power supply brackets. The plurality of power supply brackets are removably disposed on the supporting tray. Each of the power supply brackets includes a bracket top plate, a first bracket side plate, and a second bracket side plate. The first bracket side plate and the second bracket side plate are respectively connected to two opposite sides of the bracket top plate. The bracket top plate, the first bracket side plate, and the second bracket side plate together define an accommodating space. The first bracket side plate has at least one first engagement structure. The second bracket side plate has at least one second engagement structure. The first bracket side plate of one of the plurality of power supply brackets and the second bracket side plate of an adjacent one of the plurality of power supply brackets are held in position by a corresponding one of the first engagement structures and a corresponding one of the second engagement structures that are removably engaged with each other. The plurality of power supplies are removably located in the accommodating spaces, respectively.

Another embodiment of the chassis disclosed in the present invention includes a chassis configured for a plurality of power supplies, and includes a supporting tray and a plurality of power supply brackets. The plurality of power supply brackets are removably disposed on the supporting tray. Each of the power supply brackets includes a bracket top plate, a first bracket side plate, and a second bracket side plate. The first bracket side plate and the second bracket side plate are respectively connected to two opposite sides of the bracket top plate. The bracket top plate, the first bracket side plate, and the second bracket side plate together define an accommodating space. Each of the these accommodating spaces are used to accommodate the power supplies. The first bracket side plate includes at least one first engagement structure. The second bracket side plate includes at least one second engagement structure. The first bracket side plate of one of the plurality of power supply brackets and the second bracket side plate of an adjacent one of the plurality of power supply brackets are held in position by a corresponding one of the first engagement structures and a corresponding one of the second engagement structures that are removably engaged with each other.

According to the electronic device and chassis of the above embodiment, since the power supply brackets include the first engagement structure and the second engagement structure, the power supply brackets can be held in position through the engagement between the first engagement structure and the second engagement structure, allowing modularization of the power supply brackets. As a result, users can assemble the power supply brackets based on the required number of power supplies without a new power supply bracket with modified specification. Furthermore, the aforementioned structural design occupies a negligible space in the supporting tray. Therefore, the flexibility for assembling the power supply brackets is enhanced to reduce the cost for assembling the power supply brackets.

### BRIEF DESCRIPTION OF THE DRAWINGS

The invention will become more fully understood from the detailed description given herein below and the accompanying drawings which are given by way of illustration only and thus are not limitative of the invention and wherein:

FIG. 1 is a schematic perspective view of an electronic device according to a first embodiment of the invention;

FIG. 2 is an schematic exploded view of the electronic device shown in FIG. 1;

FIG. 3 is an schematic exploded view of two power supply brackets of the electronic device shown in FIG. 1;

FIG. 4 is a schematic perspective view of the two power supply brackets of the electronic device shown in FIG. 1 that have not been located close to each other;

FIG. 5 is a schematic perspective view of the two power supply brackets of the electronic device shown in FIG. 1 that are located close to each other but have not been engaged with each other;

FIG. 6 is a schematic cross-sectional view of two power supply brackets of the electronic device shown in FIG. 1, that are located close to each other but have not been engaged with each other;

FIG. 7 is a schematic cross-sectional view of two power supply brackets of the electronic device shown in FIG. 1, engaged with each other;

FIG. 8 is a schematic cross-sectional view showing that another power supply bracket of the electronic device shown in FIG. 1 is fastened to the supporting tray bottom plate; and

FIG. 9 is a perspective schematic diagram of an electronic device according to a second embodiment of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

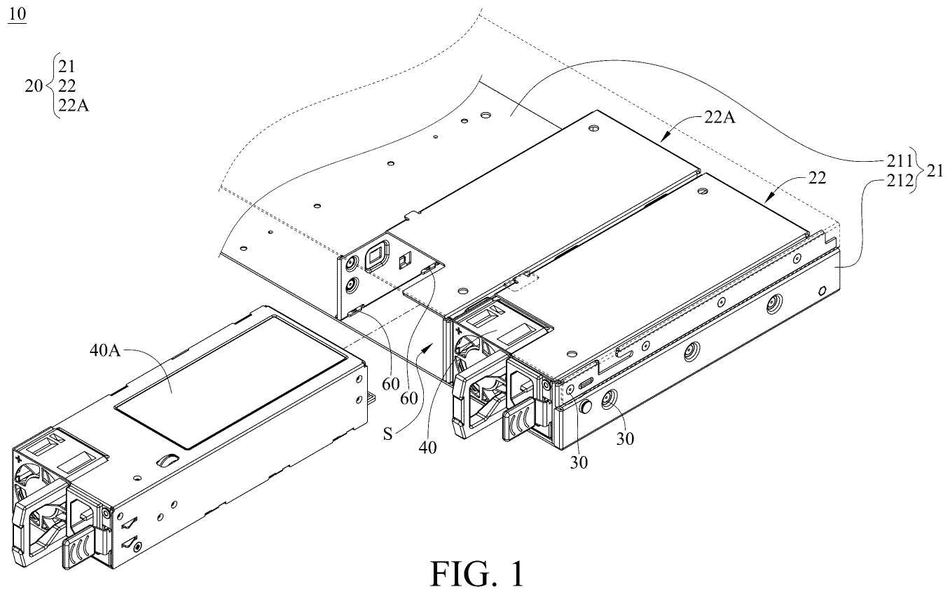

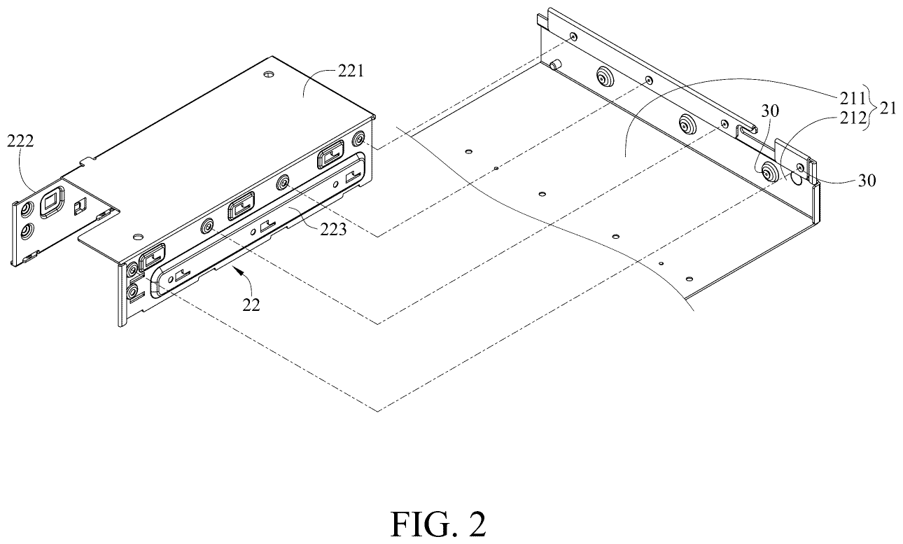

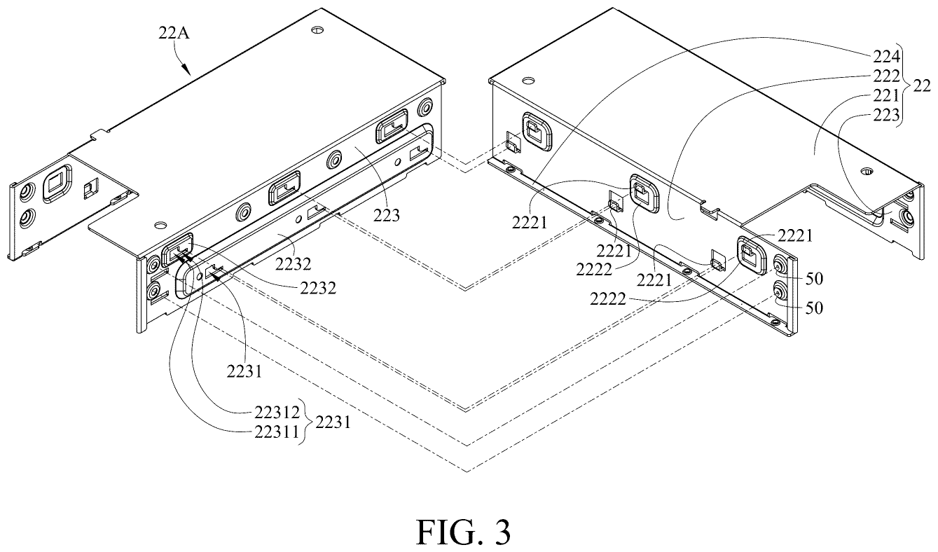

Please refer to FIG. 1 to FIG. 3. FIG. 1 is a perspective schematic diagram of an electronic device 10 according to the embodiment of the present invention. FIG. 2 is an schematic exploded view of the electronic device 10 shown in FIG. 1. FIG. 3 is an schematic exploded view of two power supply brackets 22 and 22A of the electronic device 10 shown in FIG. 1.

The electronic device 10 of this embodiment includes a chassis 20, a plurality of first fasteners 30, two power supplies 40 and 40A, and a plurality of second fasteners 50. The chassis 20 includes a supporting tray 21 and the two power supply brackets 22 and 22A. The two power supply brackets 22 and 22A are arranged side by side and are removably disposed on the supporting tray 21.

The supporting tray 21 comprises a supporting tray bottom plate 211 and a supporting tray side plate 212. The supporting tray side plate 212 is connected to the supporting tray bottom plate 211. The first fasteners 30 are disposed on the supporting tray side plate 212 and fastened to one of the two power supply brackets 22 and 22A, thereby fixing one of the power supply brackets 22 and 22A to the supporting tray side plate 212 through the first fasteners 30. The first fasteners 30 may be, for example, screws.

Since the structures of the two power supply brackets 22 and 22A are identical, only one power supply bracket 22 will be described hereinafter. Specifically, the power supply bracket 22 includes a bracket top plate 221, a first bracket side plate 222, and a second bracket side plate 223. The first bracket side plate 222 and the second bracket side plate 223 are respectively connected to two opposite sides of the bracket top plate 221.

The first fasteners 30 fasten the second bracket side plate 223 of the power supply bracket 22 to the supporting tray side plate 212. The bracket top plate 221, the first bracket side plate 222, and the second bracket side plate 223 together define an accommodating space S. The two power supplies 40, 40A are removably located in the two accommodating spaces S and are configured to supply power to other electronic components (not shown) installed within the chassis 20.

The first bracket side plate 222 has a plurality of first engagement structures 2221. The second bracket side plate 223 has a plurality of second engagement structures 2231. The first bracket side plate 222 of the power supply bracket 22 and the second bracket side plate 223 of the adjacent power supply bracket 22A are held in position by the first engagement structures 2221 and the second engagement structures 2231 removably engaged with each other.

In detail, the first engagement structures 2221 are, for example, engagement protrusions, and the second engagement structures 2231 are, for example, engagement recesses. Each second engagement structure 2231 has a wide section 22311 and a narrow section 22312. The wide section 22311 is connected to the narrow section 22312. The first engagement structure 2221 is engaged with the second engagement structure 2231 by being located in the narrow section 22312, or the engagement between the first engagement structures 2221 and the second engagement structures 2231 is released by moving the first engagement structure 2221 to the wide section 22311.

The second fasteners 50 are disposed on the first bracket side plate 222 of the power supply bracket 22 and fastened to the second bracket side plate 223 of another adjacent power supply bracket 22A, thereby fixing the two adjacent power supply brackets 22 and 22A together through the second fasteners 50. In this way, the second fasteners 50 not only hold the two power supply brackets 22 and 22A in position, but also buffers the impact caused during the engagement between the first engagement structure 2221 and the second engagement structure 2231. These second fasteners 50 may be, for example, screws.

In this embodiment, the electronic device 10 may further include multiple third fasteners 60, and each power supply bracket 22 and 22A may further include a third bracket side plate 224. The third bracket side plate 224 is connected to a side of the second bracket side plate 223 located away from the bracket top plate 221 and is fixed to the supporting tray bottom plate 211 through the third fasteners 60. The third fasteners 60 may be, for example, screws.

In this embodiment, the first bracket side plate 222 may further include multiple first protrusion structures 2222, and the second bracket side plate 223 may further include multiple second protrusion structures 2232. The first engagement structures 2221 are at least partially located on the first protrusion structures 2222, and the second engagement structures 2231 are respectively located on these second protrusion structures 2232. When the two power supply brackets 22 and 22A are held in position through the first engagement structures 2221 and the second engagement structures 2231, the first protrusion structures 2222 and the second protrusion structures 2232 are in contact with each other to create a space between the two power supply brackets 22 and 22A allowing the third fasteners 60 to fix the third bracket side plate 224 to the supporting tray bottom plate 211.

In this embodiment, since the power supply brackets 22 and 22A include the first engagement structure 2221 and the second engagement structure 2231, the power supply brackets 22 and 22A can be held in position through the engagement between the first engagement structure 2221 and the second engagement structure 2231, allowing modularization of the power supply brackets 22 and 22A. As a result, users can assemble the power supply brackets 22 and 22A based on the required number of power supplies 40, 40A without a new power supply bracket with modified specification. Furthermore, the aforementioned structural design occupies a negligible space in the supporting tray 21. Therefore, the flexibility for assembling the power supply brackets 22 and 22A is enhanced to reduce the cost for assembling the power supply brackets 22 and 22A.

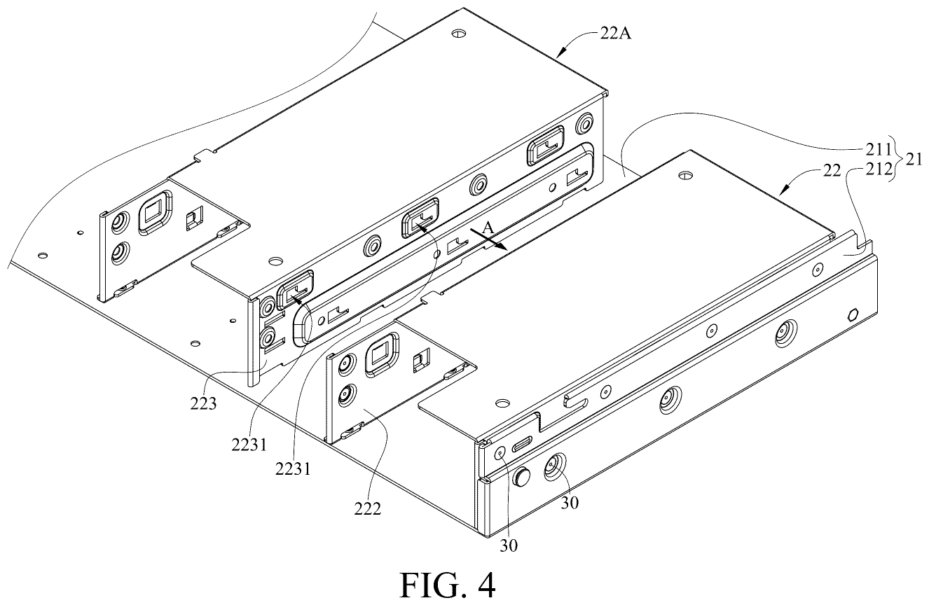

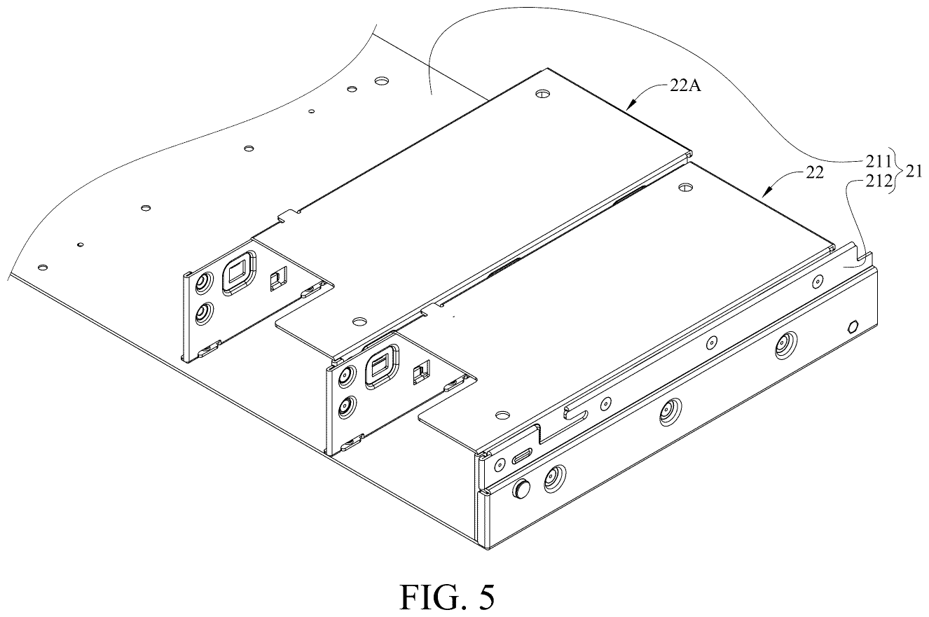

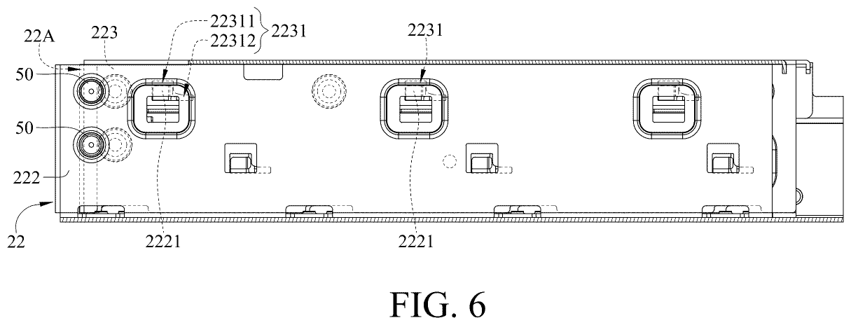

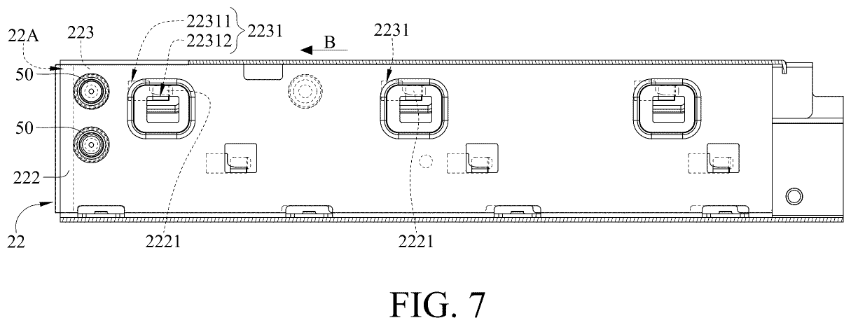

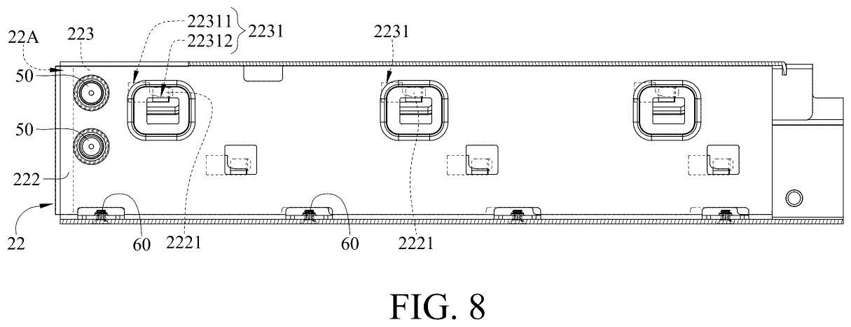

Please refer to FIG. 4 to FIG. 8. FIG. 4 is a perspective schematic diagram showing two power supply brackets before they are brought close together in the electronic device of FIG. 1. FIG. 5 is a perspective schematic diagram showing two power supply brackets before they engage with each other in the electronic device of FIG. 1. FIG. 6 is a cross-sectional schematic diagram showing two power supply brackets before engagement in the electronic device of FIG. 1. FIG. 7 is a cross-sectional schematic diagram showing two power supply brackets after engagement in the electronic device of FIG. 1. FIG. 8 is a cross-sectional schematic diagram showing one of the power supply brackets secured to the supporting tray bottom plate in the electronic device of FIG. 1. For the illustration of the assembly process of the power supply brackets 22 and 22A, some structures of the power supply brackets 22 and 22A are simplified in FIG. 6 to FIG. 8 to maintain the brevity of the drawings.

In this embodiment, the two power supply brackets 22 and 22A is installed on the supporting tray 21 by the following steps. First, as shown in FIGS. 4 to 6, the power supply bracket 22 is fixed to the supporting tray side plate 212 by the first fasteners 30 and fixed to the supporting tray bottom plate 211 by the third fasteners 60. Then, the power supply bracket 22A is inserted into the supporting tray 21 along a direction A and disposed on the side of the power supply bracket 22 located away from the supporting tray side plate 212. At this point, the first engagement structures 2221 of the power supply bracket 22 are respectively located in the wide sections 22311 of the second engagement structures 2231 of the power supply bracket 22A.

Then, as shown in FIG. 7, the power supply bracket 22A is moved along a direction B to allow the first engagement structures 2221 to be engaged with the second engagement structures 2231 by moving the first engagement structures 2221 of the power supply bracket 22 to the narrow sections 22312 of the second engagement structures 2231 of the power supply bracket 22A, and the two power supply brackets 22 and 22A are fixed together through the second fasteners 50. Then, as shown in FIG. 8, the power supply bracket 22A is fixed to the supporting tray bottom plate 211 in FIG. 3 by the third fasteners 60. So far, the process for assembling the two power supply brackets 22 and 22A on the supporting tray 21 is completed.

Conversely, the two power supply brackets 22 and 22A is removed from the supporting tray 21 by the following steps. First, the fixation between the power supply bracket 22A and the supporting tray bottom plate 211 is released by removing the third fasteners 60 and the fixation between the two power supply brackets 22 and 22A is released by removing the second fasteners 50. Then, the power supply bracket 22A is moved along a direction opposite to a direction B, so that the first engagement structures 2221 of the power supply bracket 22 are moved to the wide sections 22311 of the second engagement structures 2231 of the power supply bracket 22A, thereby disengaging the first engagement structures 2221 from the second engagement structures 2231. Then, the power supply bracket 22A is moved along a direction opposite to the direction A to be removed from the power supply bracket 22 and the supporting tray 21.

Then, the fixation between the first fasteners 30 and the supporting tray side plate 212, and the fixation between the third fasteners 60 and the supporting tray bottom plate 211 are released from the power supply bracket 22. Then, the power supply bracket 22 is removed from the supporting tray 21. So far, the removal of the two power supply brackets 22 and 22A from the supporting tray 21 is completed.

In this embodiment, there are multiple first engagement structures 2221 and second engagement structures 2231, but the invention is not limited thereto. In other embodiments, there may be one first engagement structure and one second engagement structure.

In this embodiment, the first engagement structures 2221 are engagement protrusions, and the second engagement structures 2231 are engagement recesses, but the invention is not limited thereto. In other embodiments, the configurations of the first and second engagement structures may be exchanged. That is, the first engagement structures may be engagement recesses, and the second engagement structures may be engagement protrusions.

In this embodiment, there are multiple first fasteners 30, second fasteners 50, and third fasteners 60, but the invention is not limited thereto. In other embodiments, there may be one first fasteners, second fasteners, and third fasteners.

In this embodiment, the first fastener 30, second fastener 50, and third fastener 60 are screws, but the invention is not limited thereto. In other embodiments, the first fastener 30, second fastener 50, and third fastener 60 may be rivets.

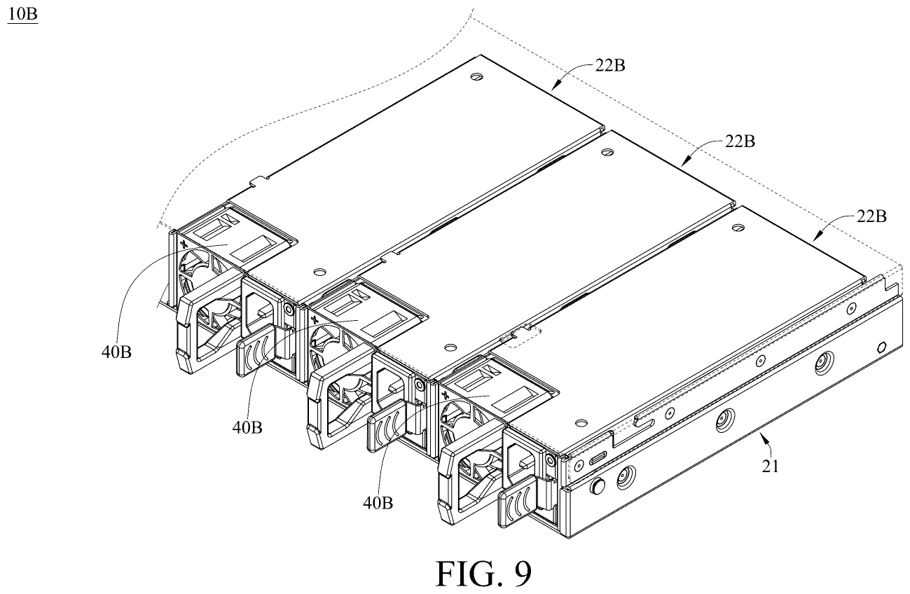

In this embodiment, there are two power supply brackets 22 and 22A and two power supplies 40, 40A, but the invention is not limited thereto. In other embodiments, please refer to FIG. 9. FIG. 9 is a perspective schematic diagram of the electronic device according to the second embodiment of the present invention. The electronic device 10B of this embodiment is similar to the electronic device 10 of the first embodiment, so the following explanation will focus on the differences between this embodiment and the first embodiment, and the other similar aspects will not be reiterated. There are three power supply brackets 22B and three power supplies 40B. In other embodiments, there may be four or more, or one power supply brackets, and power supplies.

According to the electronic device and chassis of the above embodiment, since the power supply brackets include the first engagement structure and the second engagement structure, the power supply brackets can be held in position through the engagement between the first engagement structure and the second engagement structure, allowing modularization of the power supply brackets. As a result, users can assemble the power supply brackets based on the required number of power supplies without a new power supply bracket with modified specification. Furthermore, the aforementioned structural design occupies a negligible space in the supporting tray. Therefore, the flexibility for assembling the power supply brackets is enhanced to reduce the cost for assembling the power supply brackets.

The electronic device provided in this embodiment may be applied in, for example, a server host, and the server host may apply artificial intelligence (AI) computing, edge computing, or may be used as a 5G server, a cloud server, or a Vehicle-to-everything (V2X) server.

What is claimed is:

1. An electronic device, comprising:
a chassis, comprising:
a supporting tray; and
a plurality of power supply brackets, removably disposed on the supporting tray, wherein each of the power supply brackets comprises a bracket top plate, a first bracket side plate, and a second bracket side plate, the first bracket side plate and the second bracket side plate are respectively connected to two opposite sides of the bracket top plate, the bracket top plate, the first bracket side plate, and the second bracket side plate together define an accommodating space, the first bracket side plate comprise at least one first engagement structure, and the second bracket side plate comprise at least one second engagement structure, the first bracket side plate of one of the plurality of power supply brackets and the second bracket side plate of an adjacent one of the plurality of power supply brackets are held in position by a corresponding one of the first engagement structures and a corresponding one of the second engagement structures that are removably engaged with each other; and
a plurality of power supplies, removably located in the accommodating spaces, respectively.

2. The electronic device according to claim 1, wherein the at least one first engagement structure is an engagement protrusion, and the at least one second engagement structure is a engagement recess.

3. The electronic device according to claim 2, wherein the at least one second engagement structure comprises a wide section and a narrow section, the wide section is connected to the narrow section, the at least one first engagement structure is engaged with the at least one second engagement structure by being located in the narrow section, or the engagement between the at least one first engagement structure and the at least one second engagement structure is released by moving the at least one first engagement structure to the wide section.

4. The electronic device according to claim 1, further comprising at least one first fastener, wherein the supporting tray comprises a supporting tray bottom plate and a supporting tray side plate, the supporting tray side plate is connected to the supporting tray bottom plate, the at least one first fastener is disposed on the supporting tray side plate and fastened to the second bracket side plate of one of the plurality of power supply brackets, thereby fixing one of the plurality of power supply brackets to the supporting tray side plate through the at least one first fastener.

5. The electronic device according to claim 4, further comprising at least one second fastener, wherein the at least one second fastener is disposed on the first bracket side plate of one of the plurality of power supply brackets and fastened to the second bracket side plate of an adjacent one of the plurality of power supply brackets, thereby fixing any two adjacent ones of the plurality of power supply brackets together through the at least one second fastener.

6. The electronic device according to claim 5, further comprising at least one third fastener, wherein each of the plurality of power supply brackets further comprises a third bracket side plate, the third bracket side plate is connected to a side of the second bracket side plate located away from the bracket top plate, and the third bracket side plate is fixed to the supporting tray bottom plate through the at least one third fastener.

7. A chassis, configured for a plurality of power supplies, and comprising:
a supporting tray; and
a plurality of power supply brackets, removably disposed on the supporting tray, wherein each of the power supply brackets comprises a bracket top plate, a first bracket side plate, and a second bracket side plate, wherein the first bracket side plate and the second bracket side plate are respectively connected to two opposite sides of the bracket top plate, and the bracket top plate, the first bracket side plate, and the second bracket side plate together define an accommodating space, each of the accommodating space are used to accommodate the power supplies, wherein the first bracket side plate comprises at least one first engagement structure, and the second bracket side plate comprises at least one second engagement structure, the first bracket side plate of one of the plurality of power supply brackets and the second bracket side plate of an adjacent one of the plurality of power supply brackets are held in position by a corresponding one of the first engagement structures and a corresponding one of the second engagement structures that are removably engaged with each other.

8. The chassis according to claim 7, wherein the at least one first engagement structure is an engagement protrusion, the at least one second engagement structure is an engagement recess and comprises a wide section and a narrow section, the wide section is connected to the narrow section, the at least one first engagement structure is engaged with the at least one second engagement structure by being located in the narrow section, or the engagement between the at least one first engagement structure and the at least one second engagement structure is released by moving the at least one first engagement structure to the wide section.

9. The chassis according to claim 7, further comprising at least one first fastener, at least one second fastener, and at least one third fastener, wherein the supporting tray comprises a supporting tray bottom plate and a supporting tray side plate, the supporting tray side plate is connected to the supporting tray bottom plate, the at least one first fastener is disposed on the supporting tray side plate and fastened to the second bracket side plate of one of the plurality of power supply brackets, thereby fixing one of the plurality of power supply brackets to the supporting tray side plate through the at least one first fastener, the at least one second fastener is disposed on the first bracket side plate of one of the plurality of power supply brackets and fastened to the second bracket side plate of an adjacent one of the plurality of power supply brackets, thereby fixing any two adjacent ones of the plurality of power supply brackets together through the at least one second fastener, each of the plurality of power supply brackets further comprises a third bracket side plate, the third bracket side plate is connected to a side of the second bracket side plate located away from the bracket top plate, and the third bracket side plate is fixed to the supporting tray bottom plate through the at least one third fastener.
